(19) United States
(12) Patent Application Publication
(10) Pub. No.: US 2015/0364292 A1
(43) Pub. Date: Dec. 17, 2015

(54) STAGE APPARATUS, LITHOGRAPHY APPARATUS, AND ARTICLES MANUFACTURING METHOD

(71) Applicant: CANON KABUSHIKI KAISHA, Tokyo (JP)

(72) Inventors: Tomonori Ishikawa, Fuchu-shi (JP); Nobushige Korenaga, Utsunomiya-shi (JP)

(21) Appl. No.: 14/738,508

(22) Filed: Jun. 12, 2015

(30) Foreign Application Priority Data
Jun. 17, 2014 (JP) 2014-124753

(51) Int. Cl. H01J 37/20; H01J 37/317

(52) U.S. Cl. CPC H01J 37/20; H01J 37/3174; H01J 2237/063; H01J 2237/2007; H01J 2237/31727

(57) ABSTRACT

A stage apparatus including: a magnet; a moving member configured to be supported so as to float by a magnetic force of the magnet and move in a first direction along a horizontal plane together with the magnet; and a fixed member having a magnetic material facing the magnet above the magnet in a movable area of the moving member, wherein side surfaces of the magnet in the first direction are covered by using a first magnetic field blocking surface of the moving member and a second magnetic field blocking surface of the fixed member.

### BACKGROUND OF THE INVENTION

1. Field of the Invention

One disclosed aspect of the embodiments relates to a stage apparatus, a lithography apparatus, and an articles manufacturing method.

2. Description of the Related Art

In recent years, in association with a requirement for an improvement of throughputs of lithography apparatuses used for forming circuit patterns of semiconductors, a speeding up of movement of stage apparatuses such as a wafer stage or a reticle stage is desired. As means for accommodating the speed-up requirement, a structure in which a stage is supported so as to float in a vertical direction by a magnetic force of an electromagnetic actuator is disclosed in Japanese Patent Laid-Open No. 2011-3782.

In the description in Japanese Patent Laid-Open No. 2011-3782, leakage of a magnetic field directed in a vertical direction from a magnetic field generated by an electromagnet used for a support in the vertical direction is reduced by a magnetic material facing the electromagnet. However, the magnetic field leakage may occur in a horizontal direction.

### SUMMARY OF THE INVENTION

This disclosure provides a stage apparatus advantageous for reducing magnetic field leakage in the horizontal direction from a magnet used as a support in the vertical direction.

One disclosed aspect of the embodiments relates to a stage apparatus including: a magnet; a moving member configured to be supported so as to float by a magnetic force of the magnet and move in a first direction along a horizontal plane together with the magnet; and a fixed member having a magnetic material facing the magnet above the magnet in a movable area of the moving member, wherein side surfaces of the magnet in the first direction are covered by using a first magnetic field blocking surface of the moving member and a second magnetic field blocking surface of the fixed member.

Further features of the present invention will become apparent from the following description of exemplary embodiments with reference to the attached drawings.

### BRIEF DESCRIPTION OF THE DRAWINGS

FIG. 1 is a configuration drawing of a drawing apparatus of a first embodiment.

FIGS. 2A to 2C are drawings of a stage YM viewed in a vertical direction.

FIG. 3 is a drawing illustrating a fixed unit and a movable unit of a drawing apparatus of a second embodiment.

FIG. 4 is a drawing illustrating a fixed unit and a movable unit of a drawing apparatus of a third embodiment.

FIG. 5 is a drawing illustrating a fixed unit and a movable unit of a drawing apparatus of a fourth embodiment.

### DESCRIPTION OF THE EMBODIMENTS

### First Embodiment

### Configuration of Drawing Apparatus

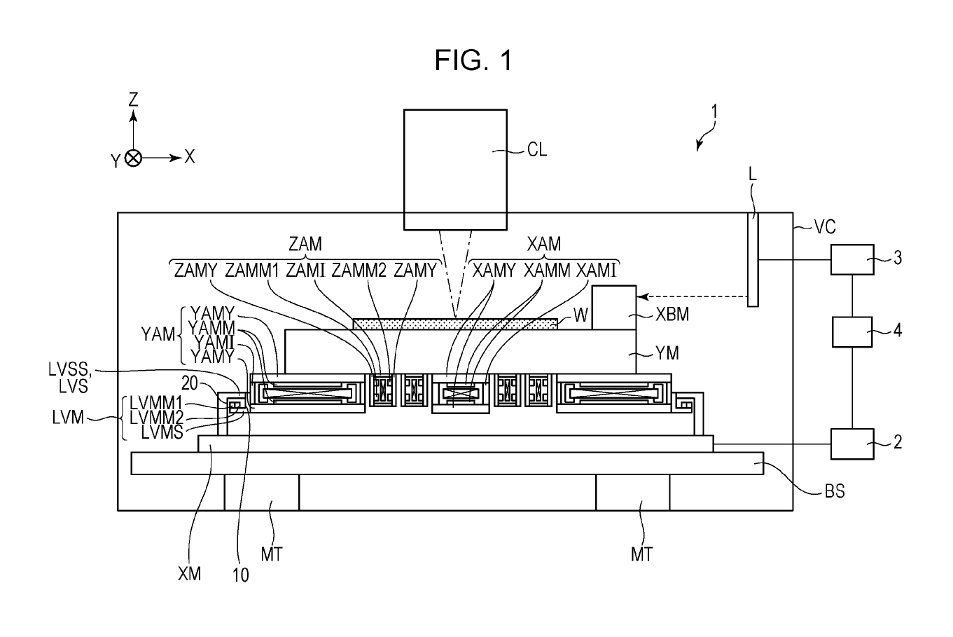

A stage apparatus of a first embodiment will be described with reference to FIG. 1. FIG. 1 is a front view of a drawing apparatus (lithography apparatus) 1 configured to form a pattern by irradiating a wafer (substrate) W having a resist applied thereto with an electron beam. A lens barrel CL includes an electron source (not illustrated) configured to generate the electron beam and an electronic optical system (not illustrated) configured to converge the electron beam emitted by the electron beam source on the wafer W. In addition, the lens barrel CL is installed so as to penetrate a vacuum chamber VC, and an interior of the vacuum chamber VC and an interior of the lens barrel CL are maintained in a vacuum atmosphere by using a vacuum pump (not illustrated).

A bottom portion in the vacuum chamber VC includes a platen BS as a base and a mount MT configured to support the platen BS and reduce external vibrations transmitted to the platen BS. A stage XM configured to be movable in an X-axis direction is provided on the platen BS. A stage YM configured to move in a state of retaining the wafer W is provided on the stage XM. The stage YM moves in the X-axis direction, a Y-axis direction (a first direction along a horizontal surface), which are horizontal directions, and a Z-axis direction, which is a vertical direction. A control unit 2 configured to control an actuator for moving the stage XM and the stage YM is connected to the stage XM and the stage YM.

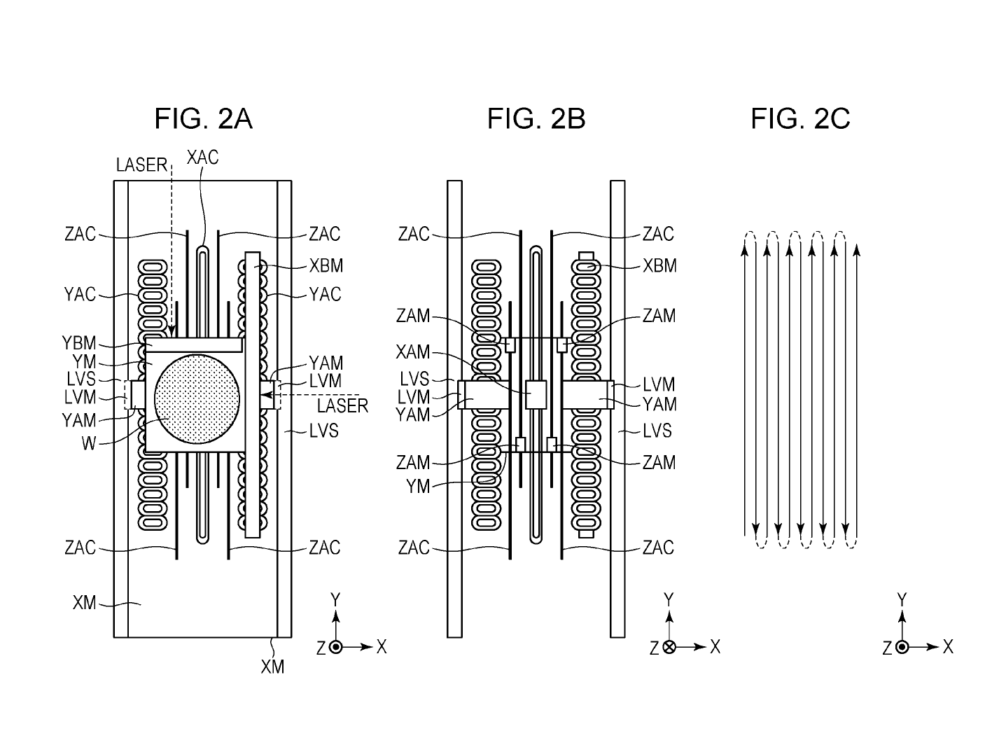

A mirror XBM used for measuring a position in the X-axis direction is provided on the stage YM. An interferometer L suspended from the vacuum chamber VC is configured to emit laser light toward the mirror XBM and detects an interfering light between the laser beam reflected by the mirror XBM and a reference light. The interferometer L measures displacement of the stage YM in the X-axis direction on the basis of a change in intensity of the interfering light. Positions in the Y-axis direction and the Z-axis direction are measured in the same manner by using a mirror YBM (illustrated in FIG. 2A) and a mirror (not illustrated) for the Z-axis direction. From the result of detection by the interferometer L, a detector 3 outputs the positions of the stage YM in the X-axis, Y-axis, and Z-axis directions.

A main control unit 4 is connected to the control unit 2 and the detector 3. The main control unit 4 gives an instruction to the control unit 2 about amounts of movement required for the stage XM and the stage YM on the basis of the result of measurement of the detector 3. The stage XM and the stage YM move in response to an instruction from the control unit 2 synchronously. The stage YM is controlled in a position in six-axis directions (X, Y, Z, ωx, ωy, and ωz).

### Detailed Configuration of Stages

A fixed unit (fixed member) LVS and a movable unit LVM support the stage YM and a member (moving member) integrated with the stage YM in a vertical direction and support these members so as to float them in a non-contact manner by a magnetic force.

The fixed unit LVS is fixed to the stage XM and, in this embodiment, is formed of a magnetic material LVSS. The movable unit LVM is provided so as to be coupled to the stage YM via a magnet unit YAM, which will be described later. The movable unit LVM moves together with the stage YM in association with the movement of the magnet unit YAM in a state of being supported in a non-contact manner with respect to the fixed unit LVS. Accordingly, the stage YM is capable of moving at a high speed without being affected by vibrations caused by cables arranged below the stage YM.

The movable unit LVM includes permanent magnets (magnets) LVMM1 and LVMM2, and a magnetic material LVMS (second magnetic material) configured to support a bottom surface of the permanent magnets LVMM1 and LVMM2. Part of an area of the magnetic material LVMS faces a side surface (surface extending in the horizontal direction) of the permanent magnet LVMM1, and constitutes a blocking surface 10 (first magnetic field blocking surface) configured to block a magnetic field generated by the permanent magnets LVMM1 and LVMM2 in the horizontal direction.

The permanent magnets LVMM1 and LVMM2 are magnetized in directions opposite to each other in the vertical direction, and are a source of an electromagnetic attraction force working with respect to the magnetic material LVSS described later. The fixed unit LVS includes the magnetic material LVSS which is located above the permanent magnets LVMM1 and LVMM2 and faces the permanent magnets LVMM1 and LVMM2. Part of an area of the magnetic material LVSS faces a side surface of the permanent magnet LVMM2 and constitutes a blocking surface 20 (second magnetic field blocking surface) configured to block a magnetic field generated by the permanent magnets LVMM1 and LVMM2 in the horizontal direction. Blocking the magnetic field means not only a case of reducing the magnetic field leaking to the periphery to zero, but also a case where the magnetic field leaking to the periphery is partially reduced.

The fixed unit LVS and the movable unit LVM have an L-shape in cross section and are arranged so as to be combined in an inverted manner in the vertical direction with respect to each other. The fixed unit LVS and the movable unit LVM have a shape extending in the Y-axis direction (illustrated in FIGS. 2A and 2B). In particular, the length of the fixed unit LVS in the Y-axis direction is longer than the length of a movable area of the movable unit LVM, that is, the length of a coil YAC, so that the fixed unit LVS serves as a guide that prevents the movement of the stage YM in the Y-axis direction from deviating significantly. In addition, the length of the blocking surface 20 in the Y-axis direction is set to be at least equal to a length of the blocking surface 10 in the Y-axis direction. In this embodiment, the length of the blocking surface 20 in the Y-axis direction is set to be equal to the length of the movable area of the movable unit LVM. Accordingly, magnetic field leakage in the horizontal direction may be reduced even during movement of the stage YM in the Y-axis direction.

The magnetic materials LVMS and LVSS are formed of a material capable of absorbing much of the magnetic field and reducing magnetic field leakage from the permanent magnets LVMM1 and LVMM2 to the outside, that is, a material having a high magnetic permeability. For example, a high magnetic permeability material having a magnetic permeability μ of 1000 or higher, such as iron, cobalt, and nickel is applicable. In particular, materials that are highly effective at preventing magnetic field leakage such as carbon steel (alloy of carbon, silicon, manganese, phosphorous, and sulfur), silicon steel (alloy of iron, silicon, and aluminum), perm alloy (alloy of iron and nickel), and the like are preferable.

In a configuration of this embodiment, the magnetic material of either the fixed unit LVS or the movable unit LVM is absolutely present not only in the vertical direction but also in the horizontal direction of the permanent magnets LVMM1 and LVMM2. Accordingly, the leakage of the magnetic field may be reduced, and the influence of variations in the magnetic field on the drawing may also be reduced.

The narrower a width of a gap between the fixed unit LVS and the movable unit LVM, the higher the effect of blocking the leakage of the magnetic field becomes. However, in view of a floating support function, a gap to an extent which prevents both portions from colliding is required. Therefore, the width of the gap is set to be not larger than half a length in the vertical direction of the permanent magnet and a length thereof in the X-axis direction. For example, the size of the permanent magnet in cross section is 14 mm×14 mm, and the width of the gap is 3 to 7 mm.

An actuator configured to move the stage YM is arranged on a bottom surface of the stage YM. The magnet units XAM, YAM, and ZAM are movable units of the actuator. The magnet unit XAM moves the stage YM in the X-axis direction. The two magnet units YAM move the stage YM in the Y-axis direction. The four magnet units ZAM move the stage YM in the Z-axis direction. The respective magnet units XAM, YAM, and ZAM have a hollow structure so as to allow the coils XAC, YAC, and ZAC to penetrate therethrough, the coils XAC, YAC, and ZAC being fixed units of the actuator corresponding to the respective magnet units XAM, YAM, ZAM.

The magnet unit YAM includes magnets YAMM above and below the coil YAC, and yokes YAMY are positioned above and below so as to interpose each of the magnets YAMM therebetween. The yokes YAMY are fixed to each other with an intermediate member YAMI. The magnets YAMM having different magnetic polarities are arranged alternately in the Y-axis direction.

Magnets ZAMM1 and magnets ZAMM2 of the magnet unit ZAM are each a magnet pair having magnetic polarity of opposing directions. Yokes ZAMY are arranged on side surfaces of the magnets ZAMM1 and ZAMM2, and the yokes ZAMY are fixed to each other with the intermediate member ZAMI.

The magnet unit XAM includes magnets XAMM located above and below the coil XAC, yokes XAMY arranged above and below the respective magnets, and an intermediate member XAMI fixed so as to couple the yokes XAMY. The magnets XAMM are magnets having magnetic fields extending in opposing directions in the X-axis direction.

Subsequently, a drawing of the stage YM viewed from a lower surface of the lens barrel CL is illustrated in FIG. 2A, and a drawing of the stage YM viewed from the stage XM is illustrated in FIG. 2B. As illustrated in FIGS. 2A and 2B, the stage XM has an elongated shape in the Y-axis direction. The coil XAC is a single-phase oval coil and has an elongated shape in the Y-axis direction on an XY plane. A coil ZAC is also a single-phase elongated circular coil, and is arranged so that a surface that is formed by the coil ZAC forms a right angle with a surface formed by the coil XAC. In contrast, the coil YAC is formed of a multi-phase coil and has a configuration that can achieve long-distance driving of the stage YM in the Y-axis direction.

The control unit 2 makes a current flow in the coil XAC and moves the magnet unit XAM and the stage YM in the X-axis direction by using an electromagnetic force. In the same manner, the control unit 2 makes a current flow in the coil ZAC and drives the magnet unit ZAM and the stage YM in the Z-axis direction by the electromagnetic force. In addition, the control unit 2 makes a current flow in a predetermined coil of the coil YAC in accordance with a position of the stage YM to drive the magnet unit YAM and the stage YM in the Y-axis direction.

As illustrated in FIG. 2B, the respective coils of the coil ZAC are arranged apart from each other in the X-axis direction and the Y-axis direction. Accordingly, the inclination of the stage YM can be controlled in accordance with fine concavities and convexities on the surface of the wafer W during plotting. In this manner, in response to an instruction from the control unit 2, the position of the stage YM is controlled by the magnitude of the current flowing to the respective coils and the direction and timing of the current.

The stage XM moves in the X-axis direction while being supported by a guide (not illustrated) using a rolling member and a linear motor (not illustrated). The magnet unit XAM also moves by an amount of the movement of the stage XM so that the stage XM and the stage YM move integrally in the X-axis direction. The magnet units XAM, YAM, and ZAM and the coils XAC, YAC, and ZAC are covered with a magnetic shield, which is not illustrated, and have a structure which resists leakage of the magnetic field to the periphery.

The movement of the stage XM and the stage YM draws a locus on the wafer W as illustrated in FIG. 2C. Scanning driving (solid line portion) which drives the wafer W in the Y-axis direction while irradiating the wafer with the electron beam, and step driving (broken line portion) which moves the wafer W in the X-axis direction while the electron beam is not irradiated are repeated. The distance of movement of the stage XM and the stage YM per one movement is, for example, 10 to 100 μm in the X-axis direction and 100 to 1000 mm in the Y-axis direction.

Magnetic field leakage from the permanent magnets LVMM1 and LVMM2 in the horizontal direction is prevented by the blocking surface 20 on the fixed unit LVS and the blocking surface 10 on the movable unit LVM of this embodiment. The two side surfaces of the permanent magnets LVMM1 and LVMM2 in the Y-axis direction are configured to be covered by the blocking surface 10 and the blocking surface 20. Accordingly, even in the case where the gap in the vertical direction between the fixed unit LVS and the movable unit LVM is changed by the magnet unit ZAM and the coil ZAC, the magnetic field leakage in the horizontal direction may be stably reduced.

Covering the side surfaces does not mean that the peripheries of the permanent magnets LVMM1 and LVMM2 are invisible from the outside. If specific side surfaces (side surfaces in the Y-axis direction in this embodiment) of the permanent magnets LVMM1 and LVMM2 face at least one of the blocking surface 10 and the blocking surface 20 via the gap, surfaces other than the specific side surfaces may not face other blocking surfaces.

In this configuration, a phenomenon of blocking an electromagnetic attraction force for supporting the moving unit LVM so as to float the moving unit LVM that occurs in the case where only the movable unit LVM is covered with a magnetic field blocking material may be prevented. An increase in the material cost of the magnetic field blocking material that occurs when the fixed unit LVS and the movable unit LVM are entirely covered is also prevented.

A static magnetic field generated by the permanent magnets LVMM1 and LVMM2 shifts the locus of the electron beam in a predetermined direction, which may cause the position where the pattern is to be drawn on the wafer W to be displaced. In addition, in the case where the stage YM is moved, the direction and the magnitude of the magnetic field in a position of irradiation by the electron beam vary. If the magnetic field in the periphery varies in association with the driving of the stage YM, synchronization of the driving of the stage YM with the correction of the position of irradiation by the electron beam is required.

According to this embodiment, since the static magnetic field in the horizontal direction generated by the permanent magnets LVMM1 and LBMM2 in the horizontal direction may be reduced, variations in the magnetic field in the periphery of the position of irradiation by the electron beam may be suppressed. Therefore, a complex correction process is not required for the position of irradiation by the electron beam.

### Second Embodiment

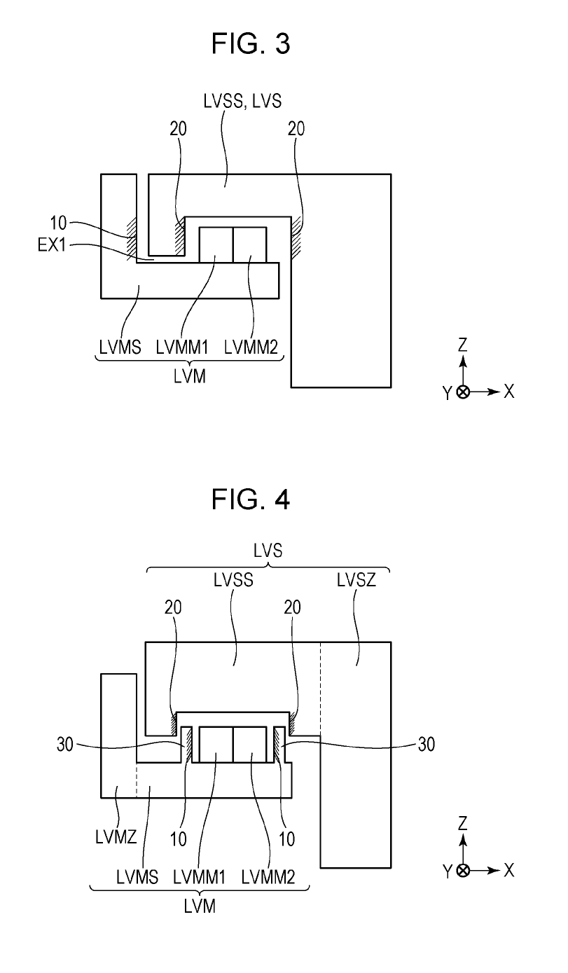

FIG. 3 illustrates a configuration of a fixed unit LVS and a movable unit LVM of a stage apparatus according to a second embodiment. The second embodiment is different from the first embodiment in that a magnetic material LVSS has a blocking surface 20 so as to face not only a side surface of a permanent magnet LVMM2, but also face a side surface of a permanent magnet LVMM1.

In this embodiment as well, the side surfaces of the permanent magnets LVMM1 and LVMM2 in the Y-axis direction are covered by combining a blocking surface 10 and the blocking surface 20 that a reduction of the magnetic field directed in the horizontal direction is achieved. In addition, in the case of this embodiment, since much of the magnetic field leaking from the permanent magnet LVMM1 and the permanent magnet LVMM2 in a −X direction is absorbed by a magnetic material LVSS having the blocking surface 20, leakage of the magnetic field in the −X direction rarely occurs.

Since the magnetic field passing through a gap EX1 is absorbed by a magnetic material LVMS having the blocking surface 10 as well, the leakage of the magnetic field to the outside rarely occurs. In this manner, the magnetic material LVSS and the magnetic material LVMS are arranged so that part of the blocking surface 10 (part of the area of a second magnetic field blocking surface) and part of the blocking surface 20 (part of the area of the blocking surface 20 blocking surface) face each other, and are overlapped with each other in the horizontal direction, so that the leakage of the magnetic field is suppressed more than in the first embodiment.

### Third Embodiment

FIG. 4 illustrates a configuration of a fixed unit LVS and a movable unit LVM of a stage apparatus according to a third embodiment. A magnetic material LVMS of the movable unit LVM includes a convex portion 30 so as to have a blocking surface 10 which faces both side surfaces of permanent magnets LVMM1 and LVMM2.

The magnetic material LVMS of the fixed unit LVM includes the convex portion 30 so as to have a blocking surface 20 which overlaps partly with the blocking surface 10 in the −X direction when viewed from the permanent magnet LVMM1. In the same manner, the convex portion 30 is formed so as to have the blocking surface 20 which partly overlaps with the blocking surface 10 also in the +X direction when viewed from the permanent magnet LVMM1. A supporting member LVSZ, which is a non-magnetic material, of the fixed unit LVS supports a magnetic material LVSS. A supporting member LVMZ, which is a non-magnetic material, of the movable unit LVM supports the magnetic material LVMS and the permanent magnets LVMM1 and LVMM2 provided on the magnetic material LVMS.

By combining the blocking surface 10 and the blocking surface 20, the side surfaces of the permanent magnets LVMM1 and LVMM2 in the Y-axis direction can be covered, and the magnetic field leaking in the horizontal direction in a space in the peripheries of the permanent magnets LVMM1 and LVMM2 is reduced. With the configuration in which part of the blocking surface 10 faces part of the blocking surface 20, and overlaps therewith in the horizontal direction, even though a height of a stage YM varies, the leakage of the magnetic field in the horizontal direction is reduced.

In this embodiment, a length of the blocking surface 20 in the vertical direction is shorter than a length of the side surfaces of the permanent magnets LVMM1 and LVMM2 in the vertical direction. In other words, the surface area that side surfaces of the permanent magnets LVMM1 and LVMM2 and the blocking surface 20 oppose in this embodiment is smaller than those in the first embodiment and the second embodiment. Accordingly, the movement of the stage YM in the horizontal direction without control due to an electromagnetic attraction force acting also in the horizontal direction could be prevented.

Even in the case where the surface area of the blocking surface 20 is small as in this embodiment, the amount of variations in the magnetic field generating when the stage YM moves in the Y-axis direction may be reduced to 1/30 or even more in comparison with the case where the blocking surface 10 and the blocking surface 20 do not exist.

### Fourth Embodiment

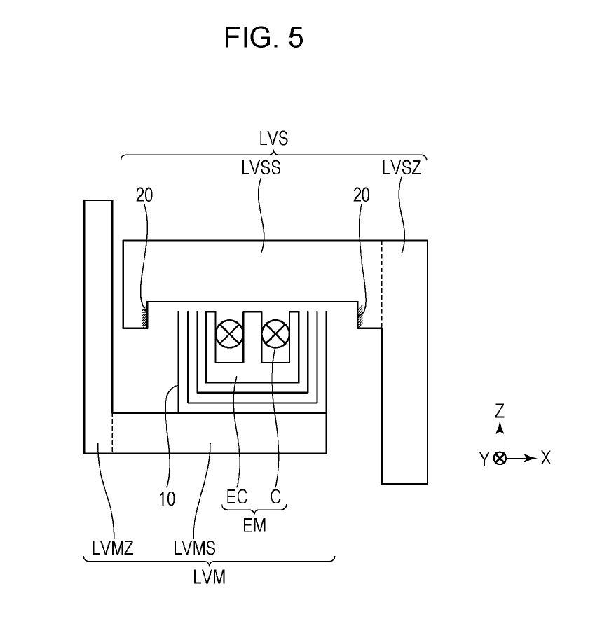

FIG. 5 illustrates a configuration of a fixed unit LVS and a movable unit LVM of a stage apparatus according to a fourth embodiment. This disclosure may be applied not only to a configuration of a support floatingly by the magnetic force of a permanent magnet, but also to a configuration of the support floatingly by the magnetic force of the electromagnet. An electromagnet EM having a coil C and an E-core EC for winding the coil C generates an electromagnetic attraction force with respect to a magnetic material LVSS and supports the floating of a stage YM.

In the same manner as the third embodiment, by arranging a blocking surface 10 and a blocking surface 20, the side surface of the E-core EC in the Y-axis direction is covered. Accordingly, the magnetic field leakage from the electromagnet EM in the horizontal direction may be reduced. In addition, since the supporting force for floating is adjustable by adjusting a current to be passed through the coil C, the electromagnet EM is capable of aiding a function as an actuator by a magnet unit ZAM and a coil ZAC.

### Other Embodiments

Finally, other embodiments which may be applied to all of the embodiments will be described. At least two side surfaces of the permanent magnet are configured to face the blocking surface that blocks the magnetic field by the magnetic material having the fixed unit LVS and the movable unit LVM. Accordingly, the magnetic field leaking in the horizontal direction may be significantly reduced. In addition, by arranging the magnetic material also in the vertical direction, variations in the magnetic field in the case where the magnetic field leakage to the periphery occurs or the stage YM moves may be significantly reduced.

In the respective embodiments described above, the magnetic material LVSS and the magnetic material LVMS are formed integrally. However, it is also possible to combine and mold different magnetic materials at bent positions of the respective magnetic materials. However, molding integrally is preferable because it is simple and an occurrence of minute magnetic field leakage from fastened points when employing different members may be suppressed.

The fixed unit LVS and the movable unit LVM may be provided on the side surface of the moving stage YM as illustrated in FIG. 1, or may be provided on the bottom surface of the stage YM. In the respective embodiments described above, the drawing apparatus using the electron beam has been exemplified. However, the stage apparatus of this disclosure may be applied to apparatuses which use a charged particle radiation and is susceptible to the magnetic field or to instruments which handles weak magnetic field.

### Method of Manufacturing Articles

A method of manufacturing articles of this disclosure (semiconductor integrated circuit elements, liquid crystal display devices, image pickup elements, magnetic heads, CD-RW, optical elements, photo masks etc.) includes exposing a pattern on a substrate (wafer or glass plate) by using the stage apparatus of the embodiment described above, and performing at least etching or ion infusion on the exposed substrate. Furthermore, other known processes (development, oxidization, film formation, depositing, flattening resist separation, dicing, bonding, packaging and the like) may be included.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-124753, filed Jun. 17, 2014 which is hereby incorporated by reference herein in its entirety.

What is claimed is:

1. A stage apparatus comprising:
a magnet;
a moving member configured to be supported so as to float by a magnetic force of the magnet and move in a first direction along a horizontal plane together with the magnet; and
a fixed member including a magnetic material facing the magnet above the magnet in a movable area of the moving member, wherein
side surfaces of the magnet in the first direction are covered by using a first magnetic field blocking surface of the moving member and a second magnetic field blocking surface of the fixed member.

2. The stage apparatus according to claim 1, wherein
a length of the second magnetic field blocking surface extending in the first direction is longer than a length of the first magnetic field blocking surface extending in the first direction.

3. The stage apparatus according to claim 1, wherein
the magnetic material facing the magnet above the magnet is a first magnetic material, and the moving member includes a second magnetic material configured to support the magnet in a contact manner below the magnet.

4. The stage apparatus according to claim 1, wherein
a part of an area of the first magnetic field blocking surface and a part of an area of the second magnetic field blocking surface face each other.

5. The stage apparatus according to claim 1, wherein
a length of the second magnetic field blocking surface in a vertical direction is shorter than a length of the magnet in the vertical direction.

6. The stage apparatus according to claim 1, wherein
a magnetic permeability of both the first magnetic field blocking surface and the second magnetic field blocking surface is 1000 or higher.

7. The stage apparatus according to claim 1, wherein
the magnet is a permanent magnet or an electromagnet.

8. A lithography apparatus configured to irradiate a substrate retained on a stage apparatus with charged particle radiation to form a pattern on the substrate, wherein
the stage apparatus comprises:
a magnet;
a moving member configured to be supported so as to float by a magnetic force of the magnet and move in a first direction along a horizontal plane together with the magnet; and
a fixed member including a magnetic material facing the magnet above the magnet in a movable area of the moving member, wherein
side surfaces of the magnet in the first direction are covered by using a first magnetic field blocking surface of the movable member and a second magnetic field blocking surface of the fixed member.

9. A method of manufacturing an article comprising:
irradiating a substrate retained in a stage apparatus with charged particle radiation by using a lithography apparatus configured to form a pattern on the substrate, and irradiating the substrate with the charged particle radiation; and
developing the substrate irradiated in the irradiating process, wherein
the stage apparatus includes:
a magnet;
a moving member configured to be supported so as to float by a magnetic force of the magnet and move in a first direction along a horizontal plane together with the magnet; and
a fixed member including a magnetic material facing the magnet above the magnet in a movable area of the moving member, wherein
side surfaces of the magnet in the first direction are covered by using a first magnetic field blocking surface of the movable member and a second magnetic field blocking surface of the fixed member.
